(19) United States
(12) Patent Application Publication
(10) Pub. No.: US 2024/0145265 A1
(43) Pub. Date: May 2, 2024

(54) PROCESS FLUID TREATMENT APPARATUS, AND WAFER CLEANING APPARATUS AND SEMICONDUCTOR MANUFACTURING EQUIPMENT INCLUDING SAME

(71) Applicant: SEMES CO., LTD., Cheonan-si (KR)

(72) Inventors: Young Seop CHOI, Cheonan-si (KR); Myung A JEON, Yeosu-si (KR); Dong Uk LEE, Seoul (KR); Boo Seok YANG, Busan (KR); Bok Kyu LEE, Cheonan-si (KR)

(73) Assignee: SEMES CO., LTD., Cheonan-si (KR)

(21) Appl. No.: 18/141,416

(22) Filed: Apr. 29, 2023

(30) Foreign Application Priority Data
Nov. 1, 2022 (KR) 10-2022-0143989

(51) Int. Cl. H01L 21/67; B08B 3/10

(52) U.S. Cl. CPC H01L 21/67051; B08B 3/10; B08B 2203/005; B08B 2203/007

(57) ABSTRACT

Proposed are a process fluid treatment apparatus capable of decomposing ozone in a process fluid more effectively, and a wafer cleaning apparatus and semiconductor manufacturing equipment including the same. The process fluid treatment apparatus treats the process fluid used for cleaning a wafer in the semiconductor manufacturing equipment, and includes a housing having an inner space configured to contain the process fluid, a spray nozzle configured to spray the process fluid containing ozone into the inner space in the form of mist, and a nozzle heater configured to heat the process fluid passing through the spray nozzle.

### CROSS-REFERENCE TO RELATED APPLICATION

The present application claims priority to Korean Patent Application No. 10-2022-0143989, filed on Nov. 1, 2022, the entire contents of which is incorporated by reference herein for all purposes.

### BACKGROUND

### Field of the Invention

The present disclosure relates to a process fluid treatment apparatus for treating a process fluid used in wafer cleaning, and a wafer cleaning apparatus and semiconductor manufacturing equipment including the same.

### Description of the Related Art

Semiconductor manufacturing is a process of manufacturing semiconductor products capable of processing electrical signals. The semiconductor manufacturing process can be broadly divided into a processing process (front-end process) of forming a pattern on a wafer through processing steps such as oxidation, exposure, etching, ion implantation, and deposition; and a packaging process (back-end process) of manufacturing a semiconductor package through steps such as dicing, die bonding, wiring, molding, marking, and testing of the pattern-formed wafer.

Such various processes generate organic and inorganic foreign substances as byproducts which remain on the wafer. Thus, it is vital to effectively remove these foreign substances on the wafer in order to improve manufacturing yield. In general, removal of foreign substances is achieved by a cleaning process using a process fluid. The cleaning process works by supplying a processing liquid (process fluid) to an upper or rear surface of the wafer while rotating a spin chuck supporting the wafer. After the cleaning process, a rinsing process using a rinsing liquid and a drying process using a drying gas are followed.

Meanwhile, the process fluid may contain ozone. This ozone has to be separated from the process fluid when the process fluid is discharged after use. Regarding a method for separating ozone from the process fluid, Korean Patent No. 10-2020230 discloses a technique that sprays the process fluid onto a striking plate to cause the process fluid to collide with the striking plate and raises the temperature of the process fluid using a heater in a circulation line. However, since water, which is the main component of the process fluid, has a high specific heat, the temperature increase effect is insignificant and consequently the ozone decomposition effect is low.

The foregoing is intended merely to aid in the understanding of the background of the present disclosure, and is not intended to mean that the present disclosure falls within the purview of the related art that is already known to those skilled in the art.

### SUMMARY

Accordingly, the present disclosure has been made keeping in mind the above problems occurring in the related art, and an objective of the present disclosure is to provide a process fluid treatment apparatus capable of decomposing ozone in a process fluid more effectively, and provide a wafer cleaning apparatus and semiconductor manufacturing equipment including the same.

In order to achieve the above objective, according to one aspect of the present disclosure, there is provided a process fluid treatment apparatus for treating a process fluid used for cleaning a wafer in semiconductor manufacturing equipment, the process fluid treatment apparatus including: a housing having an inner space configured to contain the process fluid; a spray nozzle configured to spray the process fluid containing ozone into the inner space in the form of mist; and a nozzle heater configured to heat the process fluid passing through the spray nozzle.

According to an embodiment of the present disclosure, the nozzle heater may be provided as a heating wire mounted in an inner flow path of the spray nozzle.

According to an embodiment of the present disclosure, the nozzle heater may be provided as a heating wire mounted on an outside of the spray nozzle.

According to an embodiment of the present disclosure, the nozzle heater may be provided as a heater jacket surrounding an outside of the spray nozzle.

According to an embodiment of the present disclosure, the spray nozzle may be made of SUS316 stainless steel.

According to an embodiment of the present disclosure, the process fluid treatment apparatus may further include a circulation line configured to provide a path allowing the process fluid contained in the housing to be circulated therethrough, and the process fluid circulated along the circulation line may be sprayed in the form of mist through the spray nozzle.

According to an embodiment of the present disclosure, the process fluid treatment apparatus may further include a gas supply pipe configured to supply a decomposition gas that promotes decomposition of ozone in the process fluid.

According to an embodiment of the present disclosure, the process fluid treatment apparatus may further include a gas heater mounted on the gas supply pipe and configured to heat the decomposition gas supplied into the inner space.

According to another aspect of the present disclosure, there is provided a wafer cleaning apparatus of semiconductor manufacturing equipment, the wafer cleaning apparatus including: a process fluid supply apparatus configured to supply a process fluid for cleaning a wafer; a process chamber configured to perform cleaning processing for the wafer by supplying the process fluid to the wafer; and a process fluid treatment apparatus configured to treat the process fluid used for cleaning the wafer. The process fluid treatment apparatus may include: a housing having an inner space configured to contain the process fluid; a spray nozzle configured to spray the process fluid containing ozone into the inner space in the form of mist; and a nozzle heater configured to heat the process fluid passing through the spray nozzle.

According to an embodiment of the present disclosure, the process fluid treatment apparatus may be connected to the process chamber through a discharge pipe, and the spray nozzle may be connected to the discharge pipe and spray the process fluid introduced through the discharge pipe into the inner space in the form of mist.

According to an embodiment of the present disclosure, the process chamber may include a supply nozzle configured to supply the process fluid to the wafer; and a recovery cup configured to recover the process fluid supplied to the wafer.

According to an embodiment of the present disclosure, the process chamber may include a plurality process chambers, the process fluid supply apparatus may supply the process fluid to the plurality of process chambers, and the process fluid treatment apparatus may treat the process fluid recovered from the plurality of process chambers.

According to another aspect of the present disclosure, there is provided semiconductor manufacturing equipment including: an index module configured to handle a wafer fed into the semiconductor manufacturing equipment; and a process processing module including a wafer cleaning apparatus configured to perform cleaning processing for the wafer. The wafer cleaning apparatus may include: a process fluid supply apparatus configured to supply a process fluid for cleaning the wafer; a process chamber configured to perform cleaning processing for the wafer by supplying the process fluid to the wafer; and a process fluid treatment apparatus configured to treat the process fluid used for cleaning the wafer. The process fluid treatment apparatus may include: a housing having an inner space configured to contain the process fluid; a spray nozzle configured to spray the process fluid containing ozone into the inner space in the form of mist; and a nozzle heater mounted to the spray nozzle and configured to heat the process fluid passing through the spray nozzle.

According to the present disclosure, by mounting the nozzle heater to the spray nozzle for spraying the process fluid in the form of mist, it is possible to spray the process fluid containing ozone in the form of high-temperature mist, thereby effectively decomposing ozone in the process fluid.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating the layout of semiconductor manufacturing equipment according to the present disclosure;

FIGS. 2 and 3 are views illustrating the configuration of a wafer cleaning apparatus according to the present disclosure;

FIG. 4 is a view illustrating a process fluid treatment apparatus according to the present disclosure;

FIGS. 5 to 7 are views illustrating examples of a spray nozzle provided with a nozzle heater in the process fluid treatment apparatus according to the present disclosure;

FIG. 8 is a view illustrating an example of a nozzle heater configured as a heater jacket; and

FIGS. 9A and 9B are graphs illustrating the ozone decomposition performance of a process fluid treatment apparatus according to the related art and the process fluid treatment apparatus according to the present disclosure, respectively.

### DETAILED DESCRIPTION

Hereinafter, exemplary embodiments of the present disclosure will be described in detail with reference to the accompanying drawings such that the present disclosure can be easily embodied by one of ordinary skill in the art to which this disclosure belongs. The present disclosure may, however, be embodied in many different forms and should not be construed as being limited to only the embodiments set forth herein.

For clarity, a description of parts not related to describing the present disclosure is omitted here, and the same reference numerals are allocated to the same or similar components throughout the disclosure.

Components having the same structure in various embodiments will be allocated the same reference numeral and explained only in a representative embodiment, and components which are different from those of the representative embodiment will be described in the other embodiments.

It will be understood that when an element is referred to as being “connected to (or coupled to)” another element, the element can be directly connected to (or coupled to) the other element or be indirectly connected to (or coupled to) the other element having an intervening element therebetween. It will be further understood that the terms “comprises” and/or “comprising” when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

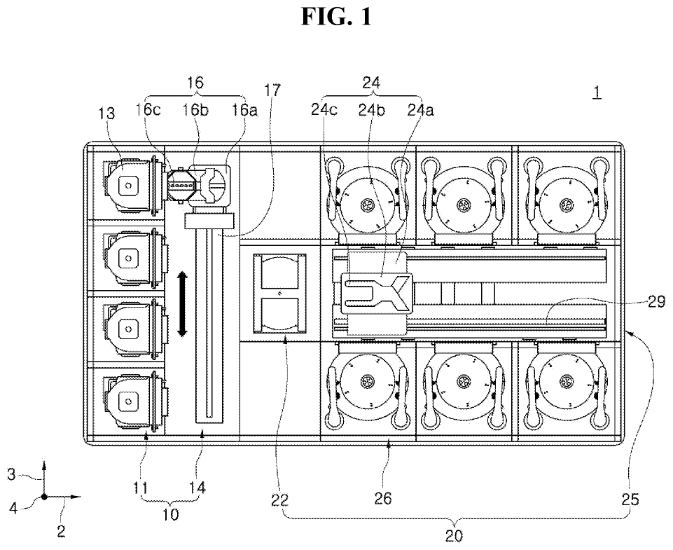

FIG. 1 is a view illustrating the layout of semiconductor manufacturing equipment 1 according to the present disclosure. The semiconductor manufacturing equipment 1 according to the present disclosure may include an index module 10 for handling a wafer fed into the semiconductor manufacturing equipment 1 and a process processing module 20 including a wafer cleaning apparatus 30 for performing cleaning processing for the wafer.

The index module 10 may include a load port 11 and a transfer frame 14. The load port 11, the transfer frame 14, and the process processing module 20 may be sequentially arranged in a line. Hereinafter, a direction in which the load port 11, the transfer frame 14, and the process processing module 20 are arranged is referred to as a first direction 2. And when viewed from above, a direction orthogonal to the first direction 2 is referred to as a second direction 3, and a direction orthogonal to a plane including the first direction 2 and the second direction 3 is referred to as a third direction 4.

A carrier 13 for storing a wafer may be placed on the load port 11. A plurality of load ports 11 may be provided. The load ports 11 may be arranged in a line along the second direction 3. In FIG. 1, it is illustrated that four load ports 11 are provided. However, the number of the load ports 11 may be increased or decreased according to process efficiency and footprint conditions of the process processing module 20. The carrier 13 may be provided with a slot (not illustrated) for supporting an edge of the wafer. A plurality of slots may be provided along the third direction 4. Here, a plurality of wafers may be positioned in the carrier 13 to be stacked and spaced apart from each other along the third direction 4. As the carrier 13, a front opening unified pod (FOUP) may be used.

The process processing module 20 may include a buffer unit 22, a transfer chamber 25, and a process chamber 26. The transfer chamber 25 may be disposed such that a longitudinal direction thereof is parallel to the first direction 2. A plurality of process chambers 26 may be disposed on each side of the transfer chamber 25 along the second direction 3. The process chambers 26 located on a first side of the transfer chamber 25 and the process chambers 26 located on a second side of the transfer chamber 25 may be provided symmetrically with respect to the transfer chamber 25. Parts of the process chambers 26 may be disposed along the longitudinal direction of the transfer chamber 25. In addition, parts of the process chambers 26 may be stacked on top of each other. That is, the process chambers 26 may be disposed in an A×B arrangement (where A and B are each a natural number of equal to or greater than 1) on one side of the transfer chamber 25. Here, A is the number of the process chambers 26 provided in a line along the first direction 2, and B is the number of the process chambers 26 provided in a line along the third direction 4. When four or six process chambers 26 are provided on one side of the transfer chamber 25, the process chambers 26 may be disposed in a 2×2 or 3×2 arrangement. The number of the process chambers 26 may be increased or decreased. Unlike the above description, the process chambers 26 may be provided on only one side of the transfer chamber 25. In addition, the process chambers 26 may be provided on one side or both side of the transfer chamber 25 in a single layer structure.

The buffer unit 22 may be disposed between the transfer frame 14 and the transfer chamber 25. The buffer unit 22 may provide a space where the wafer stays before being transferred between the transfer chamber 25 and the transfer frame 14. The buffer unit 22 may be provided with a slot (not illustrated) in which the wafer is placed. A plurality of slots (not illustrated) may be provided so as to be spaced apart from each other along the third direction 4. The buffer unit 22 may have open opposite surfaces facing the transfer frame 14 and the transfer chamber 25, respectively.

The transfer frame 14 may transfer the wafer between the carrier 13 placed on the load port 11 and the buffer unit 22. The transfer frame 14 may be provided with an index rail 17 and an index robot 16. The index rail 17 may be disposed such that a longitudinal direction thereof is parallel to the second direction 3. The index robot 16 may be installed on the index rail 17, and may be moved linearly along the second direction 3 on the index rail 17. The index robot 16 may include a base 16a, a body 16b, and an index arm 16c. The base 16a may be moved along the index rail 17. The body 16b may be coupled to the base 16a. The body 16b may be moved along the third direction 4 on the base 16a. In addition, the body 16b may be rotated on the base 16a. The index arm 16c may be coupled to the body 16b, and may be moved forward and backward with respect to the body 16b. A plurality of index arms 16c may be provided to be individually driven. The index arms 16c may be stacked and spaced apart from each other along the third direction 4. Parts of the index arms 16c may be used to transfer the wafer from the process processing module 20 to the carrier 13, and the remaining parts of the index arms 16c may be used to transfer the wafer from the carrier 13 to the process processing module 20. This may be to prevent particles generated from the wafer before a processing process from being attached to the wafer after the processing process while the index robot 16 loads and unloads the wafer.

The transfer chamber 25 may transfer the wafer between the buffer unit 22 and the process chambers 26 and between the process chambers 26. The transfer chamber 25 may be provided with a guide rail 29 and a main robot 24. The guide rail 29 may be disposed such that a longitudinal direction thereof is parallel to the first direction 2. The main robot 24 may be installed on the guide rail 29, and may be moved linearly along the first direction 2 on the guide rail 29. The main robot 24 may include a base 24a, a body 24b, and a main arm 24c. The base 24a may be moved along the guide rail 29. The body 24b may be coupled to the base 24a. The body 24b may be moved along the third direction 4 on the base 24a. In addition, the body 24b may be rotated on the base 24a. The main arm 24c may be coupled to the body 24b, and may be moved forward and backward with respect to the body 24b. A plurality of main arms 24c may be provided to be individually driven. The main arms 24c may be stacked and spaced apart from each other along the third direction 4. Parts of the main arms 24c may be used to transfer the wafer from the buffer unit 22 to the process chambers 26, and the remaining parts of the main arms 24c may be used to transfer the wafer from the process chambers 26 to the buffer unit 22.

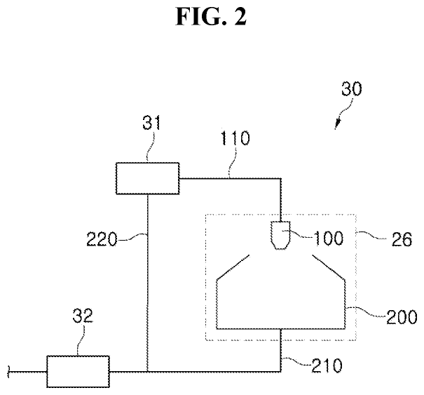

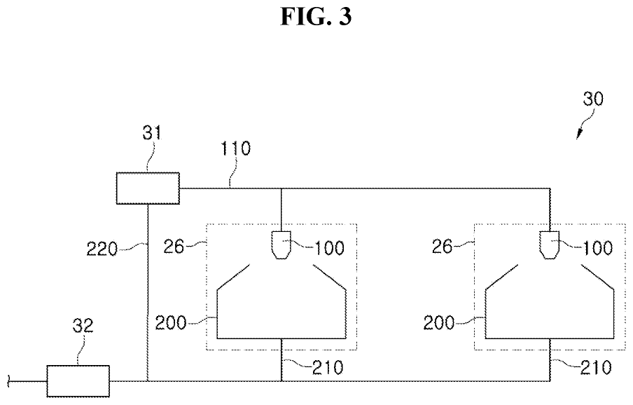

The process processing module 20 may be provided with the wafer cleaning apparatus 30 that performs cleaning processing for the wafer. The wafer cleaning apparatus 30 may include a process chamber 26, and configurations for storing a process fluid supplied to the process chamber 26, treating the process fluid recovered after use in the process chamber 26, and discharging the process fluid after treatment. Hereinafter, the configuration of the wafer cleaning apparatus 30 according to the present disclosure will be described with reference to FIGS. 2 and 3.

The wafer cleaning apparatus 30 may include a process fluid supply apparatus 31 for supplying the process fluid for cleaning a wafer, the process chamber 26 for performing cleaning processing for the wafer by supplying the process fluid to the wafer, and a process fluid treatment apparatus 32 for treating the process fluid used to clean the wafer. Referring to FIG. 2, the process chamber 26 may be connected to the process fluid supply apparatus 31 and the process fluid treatment apparatus 32. The process fluid may be ozone water or a mixture of ozone water and a chemical liquid. The process fluid supply apparatus 31 may supply the process fluid to a supply nozzle 100 through a supply pipe 110. The process fluid treatment apparatus 32 may be connected to the process chamber 26 through a first discharge pipe 210. In addition, the process fluid treatment apparatus 32 may be connected to the process fluid supply apparatus 31 through a second discharge pipe 220.

The process chamber 26 may include the supply nozzle 100 for supplying the process fluid to the wafer and a recovery cup 200 for recovering the process fluid supplied to the wafer. Although in FIG. 2, the process fluid supply apparatus 31 is illustrated as being connected to one process chamber 26, the process fluid supply apparatus 31 may be connected to two or more process chambers 26 as illustrated in FIG. 3. That is, a plurality of process chambers 26 may be provided. Here, the process fluid supply apparatus 31 may supply the process fluid to the plurality of process chambers 26, and the process fluid treatment apparatus 32 may treat the process fluid recovered from the plurality of process chambers 26.

The process fluid supplied to the wafer through the supply nozzle 100 and performing a process is collected in the recovery cup 200 and then discharged through the first discharge pipe 210 connected to the recovery cup 200. Here, the process fluid collected through the recovery cup 200 may be supplied to the process fluid supply apparatus 31 through a separate recovery pipe (not illustrated) connected to the first discharge pipe 210 and the process fluid supply apparatus 31.

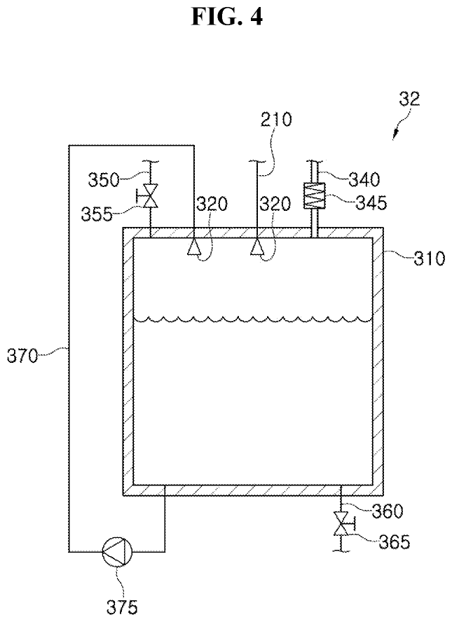

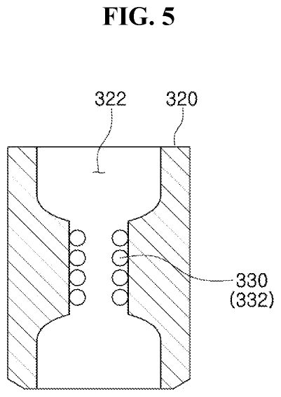

FIG. 4 is a view illustrating the process fluid treatment apparatus 32 according to the present disclosure. FIGS. 5 to 7 are views illustrating examples of a spray nozzle 320 provided with a nozzle heater 330 in the process fluid treatment apparatus 32 according to the present disclosure.

The process fluid treatment apparatus 32 according to the present disclosure may include a housing 310 having an inner space for containing the process fluid, the spray nozzle 320 for spraying the process fluid containing ozone into the inner space in the form of mist, and the nozzle heater 330 mounted to the spray nozzle 320 to heat the process fluid sprayed through the spray nozzle 320.

The process fluid treatment apparatus 32 may be connected to the process chamber 26 through the first discharge pipe 210. The spray nozzle 320 may be connected to the first discharge pipe 210 and spray the process fluid introduced through the first discharge pipe 210 into the inner space of the housing 310 in the form of mist. The spray nozzle 320 may allow the process fluid to flow in a high-pressure state through an inner flow path 322, and allow the process fluid to flow in various directions in the form of small particles (mist) when discharged to the outside.

In addition, the process fluid treatment apparatus 32 may be connected to the process fluid supply apparatus 31 through the second discharge pipe 220. The spray nozzle 320 may be connected to the second discharge pipe 220 and spray the process fluid introduced through the second discharge pipe 220 into the inner space of the housing 310 in the form of mist.

According to the present disclosure, by mounting the nozzle heater 330 to the spray nozzle 320 for spraying the process fluid in the form of mist, the process fluid containing ozone can be sprayed in the form of high-temperature mist, and thus ozone in the process fluid can be effectively decomposed. According to the present disclosure, since the process fluid containing ozone is sprayed in the form of mist by using the spray nozzle 320 instead of a porous tube, a surface area in contact with air can be increased, thereby promoting the decomposition reaction of ozone water. Here, the higher the temperature of the process fluid, the faster the decomposition reaction of ozone water. However, the use of the spray nozzle 320 lowers the temperature due to release of vaporization heat. This is compensated by spraying ozone water in a mist form while heating the spray nozzle 320 using the nozzle heater 330. Thus, ozone in the process fluid can be quickly decomposed.

According to an embodiment of the present disclosure, the nozzle heater 330 may be provided as a heating wire 332 mounted in the inner flow path of the spray nozzle 320. Referring to FIG. 5, the nozzle heater 330 may be configured in a form in which the heating wire 332 is wound around the inner flow path through which the process fluid flows in the spray nozzle 320. The nozzle heater 330 may heat the spray nozzle 320 and the process fluid sprayed through the spray nozzle 320, so the process fluid heated by the nozzle heater 330 may be sprayed in the form of mist. Here, since the process fluid is sprayed in the form of mist at a high temperature, it is maintained in a high-temperature state despite loss of vaporization heat. This can promote the decomposition reaction of ozone water, thereby effectively decomposing ozone in the process fluid. Also, since the heating wire 332 mounted in the inner flow path of the spray nozzle 320 directly heats the process fluid, it is advantageous in terms of heat transfer efficiency. Meanwhile, the heating wire 332 may be embedded in the spray nozzle 320.

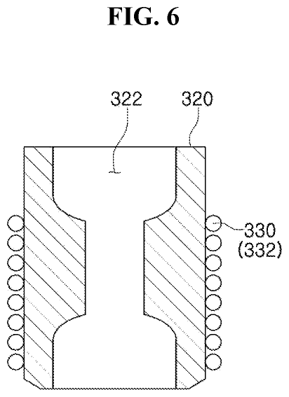

According to another embodiment of the present disclosure, the nozzle heater 330 may be provided as a heating wire 332 mounted on the outside of the spray nozzle 320. Referring to FIG. 6, the heating wire 332 may be wound around the outside of the spray nozzle 320. The heating wire 332 may indirectly heat the process fluid through the spray nozzle 320. As illustrated in FIG. 6, when the heating wire 332 is mounted on the outside of the spray nozzle 320, it is advantageous in terms of lifespan of the heating wire 332 because the heating wire 332 does not make direct contact with the process fluid.

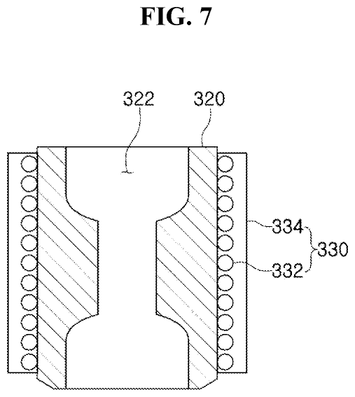

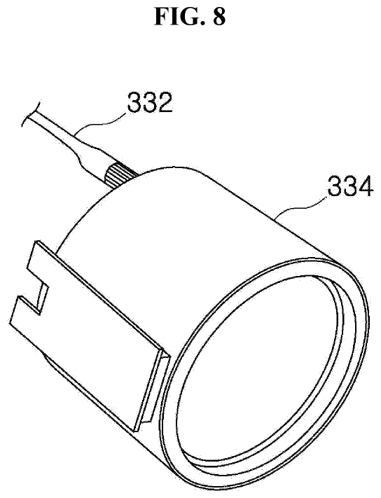

According to another embodiment of the present disclosure, the nozzle heater 330 may be provided as a heater jacket 334 surrounding the outside of the spray nozzle 320. As illustrated in FIG. 7, the heater jacket 334 may be provided in a cylindrical shape mounted on the outside of the spray nozzle 320, and may be provided with a heating wire 332 therein. Referring to FIG. 8, the heater jacket 334 may be configured to be fixed to the spray nozzle 320. The may be connected to an external power source with the heating wire 332 mounted therein. As the spray nozzle 320 is heated by the heating wire 332 provided in the heater jacket 334, and the process fluid may be heated through the spray nozzle 320. When the nozzle heater 330 is configured as the heater jacket 334 in the form illustrated in FIG. 8, a worker can more easily attach and detach the nozzle heater 330 to and from the spray nozzle 320.

According to an embodiment of the present disclosure, the spray nozzle 320 may be made of SUS316 stainless steel. Since the spray nozzle 320 is heated to 40 to 50 degrees Celsius, it needs to be made of a material with high heat transfer efficiency to the process fluid and high chemical resistance to ozone. SUS316 stainless steel is a material that satisfies these conditions and thus is suitable as a material for the spray nozzle 320 according to the present disclosure.

According to an embodiment of the present disclosure, the process fluid treatment apparatus 32 may further include a circulation line 370 for providing a path through which the process fluid contained in the housing 310 is circulated. The process fluid circulated along the circulation line 370 may be sprayed in the form of mist through the spray nozzle 320. The circulation line 370 may be provided with a pump 375 that provides power for circulation of the process fluid. The pump 375 may be located near an inlet of the circulation line 370 through which the process fluid is introduced. The pump 375 may create a pressure allowing the process fluid to flow and allow the process fluid to flow effectively while forming a turbulent flow. The pressure of the pump 375 may promote decomposition of ozone contained in the process fluid. Meanwhile, a heater (not illustrated) may be provided in the circulation line 370, but may be omitted according to embodiments.

When ozone contained in the process fluid is decomposed after a set time has elapsed, a discharge valve 365 on a process fluid discharge line 360 connected to the bottom of the housing 310 may be opened, causing the process fluid to be discharged from the housing 310. Gas inside the housing 310 may be discharged through a gas discharge line 350 by opening a gas discharge valve 355 on the gas discharge line 350. The discharge of gas inside the housing 310 may be made while ozone is decomposed.

According to an embodiment of the present disclosure, the process fluid treatment apparatus 32 may further include a gas supply pipe 340 for supplying a decomposition gas that promotes decomposition of ozone in the process fluid. In addition, the process fluid treatment apparatus 32 may further include a gas heater 345 mounted on the gas supply pipe 340 to heat the decomposition gas supplied into the inner space of the housing 310. The gas supply pipe 340 may supply the decomposition gas into the inner space of the housing 310. The decomposition gas promotes decomposition of ozone by reacting with ozone in the process fluid. The decomposition gas may be air containing oxygen. The gas heater 345 may heat the decomposition gas. By heating the decomposition gas, a reaction temperature of the decomposition gas and the process fluid can be increased, and thus decomposition of ozone can be promoted.

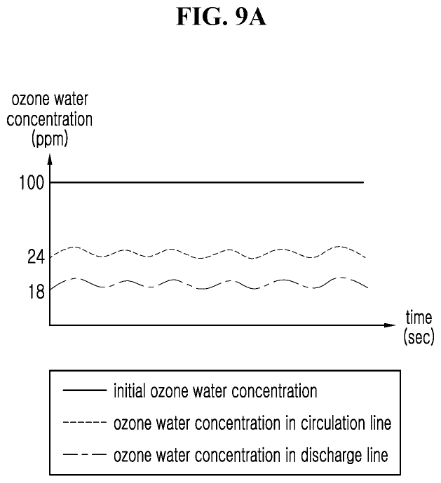

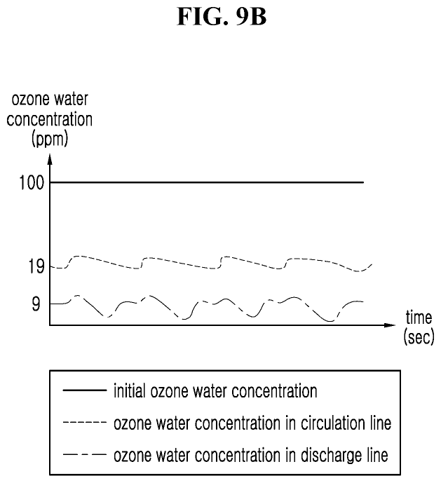

FIGS. 9A and 9B are graphs illustrating the ozone decomposition performance of a process fluid treatment apparatus according to the related art and the process fluid treatment apparatus 32 according to the present disclosure, respectively.

FIG. 9A illustrates the concentration of ozone water in the process fluid when a conventional method (a technique of heating the process fluid using a heater provided in a circulation line after discharging the process fluid to a striking plate) is applied; and FIG. 9B illustrates the concentration of ozone water in the process fluid when the process fluid is sprayed in a mist form using the spray nozzle 320 provided with the nozzle heater 330 as in the present disclosure. Referring to FIG. 9A, the concentration of ozone water contained in the process fluid initially introduced through the first discharge pipe 210 is about 100 ppm. When the conventional method is applied, the concentration of ozone water in the circulation line 370 is about 24 ppm, and the concentration of ozone water in the process fluid discharge line 360 is about 18 ppm. Referring to FIG. 9B, the concentration of ozone water contained in the process fluid initially introduced through the first discharge pipe 210 is about 100 ppm. When the process fluid is sprayed in a mist form using the spray nozzle 320 provided with the nozzle heater 330 as in the present disclosure, the concentration of ozone water in the circulation line 370 without a heater is about 19 ppm, and the concentration of ozone water in the process fluid discharge line 360 is about 9 ppm. From the above results, it is found in accordance with the present disclosure that spraying the process fluid in a mist from using the spray nozzle 320 provided with the nozzle heater 330 can achieve high decomposition efficiency of ozone in the process fluid.

While the present disclosure has been described above with reference to some embodiments and the accompanying drawings, the present disclosure, however, is not limited to only the embodiments set forth herein, and those skilled in the art will appreciate that the present disclosure can be embodied in many alternate forms.

Accordingly, the present disclosure is intended to cover not only the exemplary embodiments, but also various alternatives, modifications, equivalents, and other embodiments that may be included within the spirit and scope of the present disclosure as defined by the appended claims.

What is claimed is:

1. A process fluid treatment apparatus for treating a process fluid used for cleaning a wafer in semiconductor manufacturing equipment, the process fluid treatment apparatus comprising:
a housing having an inner space configured to contain the process fluid;
a spray nozzle configured to spray the process fluid containing ozone into the inner space in a form of mist; and
a nozzle heater configured to heat the process fluid passing through the spray nozzle.

2. The process fluid treatment apparatus of claim 1,
wherein the nozzle heater is provided as a heating wire mounted in an inner flow path of the spray nozzle.

3. The process fluid treatment apparatus of claim 1,
wherein the nozzle heater is provided as a heating wire mounted on an outside of the spray nozzle.

4. The process fluid treatment apparatus of claim 1,
wherein the nozzle heater is provided as a heater jacket surrounding an outside of the spray nozzle.

5. The process fluid treatment apparatus of claim 1,
wherein the spray nozzle is made of SUS316 stainless steel.

6. The process fluid treatment apparatus of claim 1, further comprising:
a circulation line connecting the inner space of the housing to the spray nozzle,
wherein the process fluid is supplied from the housing to the spray nozzle through the circulation line.

7. The process fluid treatment apparatus of claim 1, further comprising:
a gas supply pipe connected to the inner space of the housing to supply a decomposition gas into the inner space of the housing,
wherein the decomposition gas promotes decomposition of ozone in the process fluid.

8. The process fluid treatment apparatus of claim 7, further comprising:
a gas heater mounted on the gas supply pipe and configured to heat the decomposition gas supplied into the inner space.

9. A wafer cleaning apparatus of semiconductor manufacturing equipment, the wafer cleaning apparatus comprising:
a process fluid supply apparatus configured to supply a process fluid for cleaning a wafer;
a process chamber configured to perform cleaning processing on the wafer by supplying the process fluid to the wafer; and
a process fluid treatment apparatus configured to treat the process fluid used for cleaning the wafer,
wherein the process fluid treatment apparatus comprises:
a housing having an inner space configured to contain the process fluid;
a spray nozzle configured to spray the process fluid containing ozone into the inner space in a form of mist; and
a nozzle heater configured to heat the process fluid passing through the spray nozzle.

10. The wafer cleaning apparatus of claim 9,
wherein the process fluid treatment apparatus is connected to the process chamber through a first discharge pipe, and
wherein the spray nozzle is connected to the first discharge pipe and sprays the process fluid supplied through the first discharge pipe into the inner space in the form of mist.

11. The wafer cleaning apparatus of claim 9,
wherein the process fluid supply apparatus is connected to the process fluid treatment apparatus through a second discharge pipe, and
wherein the spray nozzle is connected to the second discharge pipe and sprays the process fluid supplied through the second discharge pipe into the inner space in the form of mist.

12. The wafer cleaning apparatus of claim 9,
wherein the process chamber comprises a plurality of process chambers,
wherein the process fluid supply apparatus supplies the process fluid to the plurality of process chambers, and
wherein the process fluid treatment apparatus treats the process fluid recovered from the plurality of process chambers.

13. The wafer cleaning apparatus of claim 9,
wherein the nozzle heater is provided as a heating wire mounted in an inner flow path of the spray nozzle.

14. The wafer cleaning apparatus of claim 9,
wherein the nozzle heater is provided as a heating wire mounted on an outside of the spray nozzle.

15. The wafer cleaning apparatus of claim 9,
wherein the nozzle heater is provided as a heater jacket surrounding an outside of the spray nozzle.

16. The wafer cleaning apparatus of claim 9,
wherein the spray nozzle is made of SUS316 stainless steel.

17. The wafer cleaning apparatus of claim 9, further comprising:
a circulation line connecting the inner space of the housing to the spray nozzle.

18. The wafer cleaning apparatus of claim 9, further comprising:
a gas supply pipe connected to the inner space of the housing to supply a decomposition gas into the inner space of the housing,
wherein the decomposition gas promotes decomposition of ozone in the process fluid.

19. The wafer cleaning apparatus of claim 18, further comprising:
a gas heater mounted on the gas supply pipe and configured to heat the decomposition gas supplied into the inner space.

20. Semiconductor manufacturing equipment comprising:
an index module configured to handle a wafer fed into the semiconductor manufacturing equipment; and
a process processing module comprising a wafer cleaning apparatus configured to perform cleaning processing on the wafer,
wherein the wafer cleaning apparatus comprises:
a process fluid supply apparatus configured to supply a process fluid for cleaning the wafer;
a process chamber configured to perform cleaning processing for the wafer by supplying the process fluid to the wafer; and
a process fluid treatment apparatus configured to treat the process fluid used for cleaning the wafer, and
wherein the process fluid treatment apparatus comprises:
a housing having an inner space configured to contain the process fluid;
a spray nozzle configured to spray the process fluid containing ozone into the inner space in a form of mist; and
a nozzle heater mounted to the spray nozzle and configured to heat the process fluid passing through the spray nozzle.
